(19) United States
(12) Patent Application Publication
(10) Pub. No.: US 2008/0265941 A1
(43) Pub. Date: Oct. 30, 2008

(54) Driving circuits

(75) Inventor: Jung-Yen Kuo, Yunlin Couty (TW)

Correspondence Address: Joe McKinney Muncy, PO Box 1364, Fairfax, VA, 22038-1364, US

(73) Assignee: PRINCETON TECHNOLOGY CORPORATION

(21) Appl. No.: 11/826,337

(22) Filed: Jul. 13, 2007

(30) Foreign Application Priority Data
Apr. 24, 2007 (TW) 096114366

(51) Int. Cl. H03K 19/0175

(52) U.S. Cl. 326/81; 326/80

(57) ABSTRACT

A driving circuit comprising an input voltage source set, a reference voltage source, a voltage level shift unit, a logic unit, a safety unit, and an output voltage terminal. The input voltage source set provides an input voltage set. The reference voltage source provides a reference voltage. The voltage level shift unit raises one of levels of the input voltage set to a level of the reference voltage. The logic unit receives the reference voltage and the input voltage set and outputs a control voltage. The safety unit conducts the control voltage to a ground. The output voltage terminal receives the control voltage and outputs an output voltage.

### BACKGROUND OF THE INVENTION

1. Field of the Invention

The invention relates to a driving circuit, and more particularly to a driving circuit for a step motor.

2. Description of the Related Art

Typically, in a conventional step motor, an H bridge circuit drives the step motor to rotate in different directions and also to stop. As shown in FIG. 1, an H bridge circuit 1 comprises four metal oxide semiconductors (MOSs). The direction of rotation of a motor 15 is controlled by turning on the first MOS 11 and the third MOS or turning on the second MOS 12 and the fourth MOS 14. The input of voltage is required at the MOS gates to turn each MOS on or off. Because a different voltage is required for turning on each MOS, a different output voltage circuit controls each MOS. Thus, the gate of each MOS is coupled to an output voltage. Voltages from the output voltage circuits control the H bridge circuit to drive a step motor.

Each output voltage circuit has an input voltage. If the input voltage is used to directly turn on a MOS, excessive power is consumed, degrading efficiency. An output voltage circuit is thus required to raise an input voltage to a sufficient level to turn on a MOS, thereby driving the H bridge circuit to operate.

Because a conventional H bridge circuit comprises four MOSs, a gate of each MOS is coupled to an output voltage circuit, and each MOS is turned on by a high level voltage output from the output voltage circuit; thus, a motor is driven. When one set of two MOSs, or a MOS pair, is turned on, the other two MOS pairs are turned off. If the MOS pair to be turned off is not actually turned off, or if the output voltages are unstable due to leakage current, the H bridge circuit may operate incorrectly and in the wrong directions, and the motor may be damaged. An output voltage circuit capable of ameliorating the described disadvantages is thus desirable.

### BRIEF SUMMARY OF THE INVENTION

Driving circuits are provided. An exemplary embodiment of a driving circuit comprises an input voltage source set, a reference voltage source, a voltage level shift unit, a logic unit, a safety unit, and an output voltage terminal. The input voltage source set provides an input voltage set. The reference voltage source provides a reference voltage. The voltage level shift unit raises one of levels of the input voltage set to a level of the reference voltage. The logic unit receives the reference voltage and the input voltage set and outputs a control voltage. The safety unit conducts the control voltage to a ground. The output voltage terminal receives the control voltage and outputs an output voltage.

Voltage level shift units are provided. An exemplary embodiment of a voltage level shift unit in a driving circuit raises an input voltage to a level of a reference voltage and comprises a plurality of metal oxide semiconductors (MOSs) and a plurality of resistors. The MOSs are coupled between an input voltage source set and a reference voltage source. The resistors are coupled between the reference voltage source and gates of the MOSs.

Motor systems are provided. An exemplary embodiment of a motor system comprises a step motor, an H bridge circuit, and a plurality of driving circuits. Each of the driving circuits comprises an input voltage source set, a reference voltage source, a voltage level shift unit, a logic unit, a safety unit, and an output voltage terminal. The input voltage source set provides an input voltage set. The reference voltage source provides a reference voltage. The voltage level shift unit raises one of levels of the input voltage set to a level of the reference voltage. The logic unit receives the reference voltage and the input voltage set and outputs a control voltage. The safety unit conducts the control voltage to a ground. The output voltage terminal receives the control voltage and outputs an output voltage.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a conventional H bridge circuit; and

FIG. 2 shows an exemplary embodiment of a driving circuit.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

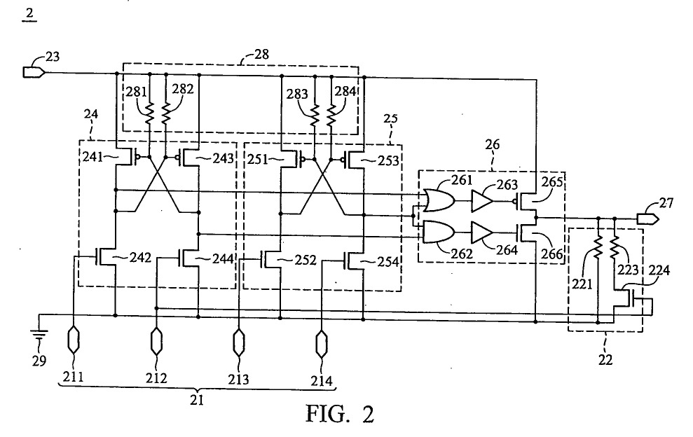

Driving circuits are provided. In an exemplary embodiment of a driving circuit in FIG. 2, a driving circuit 2 comprises an input voltage source set 21, a safety unit 22, a reference voltage source 23, a first voltage level shift unit 24, a second voltage level shift unit 25, a logic unit 26, an output voltage source 27, a stabilizing unit 28, and a ground 29. The first and second voltage level shift units are referred to as a voltage level shift unit.

The input voltage source set 21 comprises a first input voltage source 211, a second input voltage source 212, a third input voltage source 213, and a fourth input voltage source 214 inputting a first input voltage, a second input voltage, a third input voltage, and a fourth input voltage respectively. The first input voltage and the second input voltage are inverted, and, the third input voltage and the fourth input voltage are source of the fourth NMOS 254 is coupled to the ground 29, and a gate thereof is coupled to the fourth input voltage source 214.

Through the operation of the MOSs in the first and second voltage level shift units 24 and 25, the first voltage level shift unit 24 raises the voltage level of one of the first and second input voltage sources 211 and 212 in the input voltage source set 21 to the level of the reference voltage source 23, and the second voltage level shift unit 25 raises the voltage level of one of the third and fourth input voltage sources 213 and 214 in the input voltage source set 21 to the level of the reference voltage source 23

The logic unit 26 comprises a NOR gate 261, a NAND gate 262, a first inverter 263, a second inverter 264, a fifth PMOS 265, and a fifth NMOS 266. An input terminal of the NOR gate 261 is coupled to the drains of the first PMOS 241, the first NMOS 242, the fourth PMOS 253, and the fourth NMOS 254, and an output terminal thereof is coupled to an input terminal of the first inverter 263. An input terminal of the NAND gate 262 is coupled to the drains of the second PMOS 243, the second NMOS 244, the fourth PMOS 253, and the fourth NMOS 254, and an output terminal thereof is coupled to an input terminal of the second inverter 264. An output terminal of the first inverter 263 is coupled to a gate of the fifth PMOS 265, and an output terminal of the second inverter 264 is coupled to a gate of the fifth NMOS 266. The logic unit 26 generates and outputs a control voltage according to the received voltages.

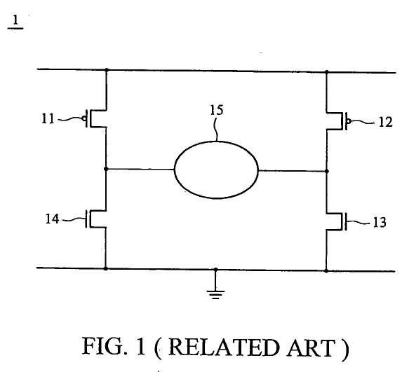

The output voltage source 27 is coupled to drains of the fifth PMOS 265 and the fifth NMOS 266. The output voltage source 27 receives and outputs the control voltage to turn the MOSs in the H bridge circuit of FIG. 1 on or off.

The safety unit 22 comprises a fifth resistor 221, a sixth resistor 223, and a seventh NMOS 224. The fifth resistor 221 is coupled between the ground 29 and the output voltage terminal 27. The sixth resistor 223 is coupled between the output voltage inverted. When the first input voltage is at a high level, the second input voltage is at a low level, conversely, when the first input voltage is at the low level, the second input voltage is at the high level. When the third input voltage is at a high level, the fourth input voltage is at a low level, conversely, when the third input voltage is at the low level, the fourth input voltage is at the high level.

The reference voltage source 23 provides a reference voltage with a constant. The reference voltage source 23 is coupled to one terminal of the first voltage level shift unit 24 and one terminal of the second voltage level shift unit 25. The other terminal of the first and the second voltage level shift unit 24 and 25 are coupled to the input voltage source set 21.

The first voltage level shift unit 24 comprises a first P-type metal oxide semiconductor (PMOS) 241, a first N-type metal oxide semiconductor (MMOS) 242, a second PMOS 243, and a second NMOS 244. The second voltage level shift unit 25 comprises a third PMOS 251, a third NMOS 252, a fourth PMOS 253, and a fourth NMOS 254. A source of the first PMOS 241 is coupled to the reference voltage source 23, and a drain thereof is coupled to a drain of the first NMOS 242. A source of the first NMOS 242 is coupled to the ground 29, and a gate thereof is coupled to the first input voltage source 211. A source of the second PMOS 243 is coupled to the reference voltage source 23, and a drain thereof is coupled to a drain of the second NMOS 244. A source of the second NMOS 244 is coupled to the ground 29, and a gate thereof is coupled to the second input voltage source 212. A source of the third PMOS 251 is coupled to the reference voltage source 23, and a drain thereof is coupled to a drain of the third NMOS 252. A source of the third NMOS 252 is coupled to the ground 29, and a gate thereof is coupled to the third input voltage source 213. A source of the fourth PMOS 253 is coupled to the reference voltage source 23, and a drain thereof is coupled to a drain of the fourth NMOS 254. A terminal 27 and the seventh NMOS 224. A gate of the seventh NMOS 224 is coupled to the second input voltage source 212, and a drain thereof is coupled to the ground 29. During normal operation, the first input voltage source 211 inputs a high level voltage, and the second input voltage source 212 inputs a low-level voltage. The operation of the driving circuit 2 is controlled through the first and second input voltage sources 211 and 212. Under some conditions, the second input voltage source 212 abnormally inputs a high level voltage. The safety unit 22 conducts the abnormally high level voltage to the ground 29 by the sixth resistor 223 and the seventh NMOS 224, preventing irregular rotation of the motor resulting from the abnormal operation of the driving circuit 2.

Typically, when the motor driving circuit 2 is supplied with power, the voltage at the input terminal of the logic unit 26 may be unstable due to power surges. When the unstable voltage is too great, a voltage which is not predetermined passes through the logic unit. The voltage level shift circuit outputs an abnormal voltage, resulting in abnormal operation. The stabilizing unit 28 comprises a first resistor 281, a second resistor 282, a third resistor 283, and a fourth resistor 284. The first resistor 281 is coupled between the reference voltage source 23 and the gate of the first PMOS 241. The second resistor 282 is coupled between the reference voltage source 23 and the gate of the second PMOS 243. The third resistor 283 is coupled between the reference voltage source 23 and the gate of the third PMOS 251. The fourth resistor 284 is coupled between the reference voltage source 23 and the gate of the fourth PMOS 253. When the motor driving circuit 2 is supplied with power, the stabilizing unit 28 fixes the voltage at the input terminal of the logic unit 26 at the same voltage level as the reference voltage, preventing abnormal voltage levels and abnormal system operation due to leakage current.

According the foregoing description, the driving circuit can effectively drive a motor. The input voltage source set 21 determines whether the motor driving circuit will operate. The voltage level shift units 24 and 25 raise an input voltage to the level of the reference voltage. The stabilizing unit 28 can prevent leakage current and unstable voltage level when the motor driving circuit is supplied. The driving circuit improves on the conventional technology.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A driving circuit comprising:
an input voltage source set providing an input voltage set;
a reference voltage source providing a reference voltage;
a voltage level shift unit raising one of levels of the input voltage set to a level of the reference voltage;
a logic unit receiving the reference voltage and the input voltage set and outputting a control voltage;
a safety unit conducting the control voltage to a ground; and
an output voltage terminal receiving the control voltage and outputting an output voltage.

2. The driving circuit as claimed in claim 1 further comprising a stabilizing unit preventing leakage resulted in the motor driving circuit and comprising a plurality of resistors coupled between the reference voltage source and the voltage level shift units.

3. The driving circuit as claimed in claim 1, wherein the input voltage source set comprises a first input voltage source, a second input voltage source, a third input voltage source, and a fourth input voltage source respectively inputting a first input voltage, a second input voltage, a third input voltage, and a fourth input voltage, the first input voltage and the second input voltage are inverted, and the third input voltage and the fourth input voltage are inverted.

4. The driving circuit as claimed in claim 3,
wherein the second input voltage is at a low level when the first input voltage is at a high level, and the second input voltage is at the high level when the first input voltage is at the low level; and
wherein the fourth input voltage is at the low level when the third input voltage is at the high level, and the fourth input voltage is at the high level when the third input voltage is at the low level.

5. The driving circuit as claimed in claim 3, wherein safety unit operates when the second input voltage at a high level.

6. The driving circuit as claimed in claim 1,
wherein the first voltage level shift unit comprises a first P-type metal oxide semiconductor (PMOS), a first N-type metal oxide semiconductor (NMOS), a second PMOS, and a second NMOS; and
wherein the second voltage level shift unit comprises a third PMOS, a third NMOS, a fourth PMOS, and a fourth NMOS.

7. The driving circuit as claimed in claim 1, wherein the logic unit comprises a NOR gate, a NAND gate, and a plurality of inverters.

8. A voltage level shift unit in a driving circuit for raising an input voltage to a level of a reference voltage, comprising:
a plurality of metal oxide semiconductors (MOSs) coupled between an input voltage source set and a reference voltage source; and
a plurality of resistors coupled between the reference voltage source and gates of the MOSs.

9. A motor system comprising a step motor, an H bridge circuit, and a plurality of driving circuits, wherein each of the driving circuits comprises:
an input voltage source set providing an input voltage set;
a reference voltage source providing a reference voltage;
a voltage level shift unit raising one of levels of the input voltage set to a level of the reference voltage;
a logic unit receiving the reference voltage and the input voltage set and outputting a control voltage;
a safety unit conducting the control voltage to a ground; and
an output voltage terminal receiving the control voltage and outputting an output voltage.

10. The motor system as claimed in claim 9 further comprising a stabilizing unit preventing leakage resulted in the motor driving circuit and comprising a plurality of resistors coupled between the reference voltage source and the voltage level shift units.

11. The motor system as claimed in claim 9, wherein the input voltage source set comprises a first input voltage source, a second input voltage source, a third input voltage source, and a fourth input voltage source respectively inputting a first input voltage, a second input voltage, a third input voltage, and a fourth input voltage, the first input voltage and the second input voltage are inverted, and the third input voltage and the fourth input voltage are inverted.

12. The motor system as claimed in claim 11,
wherein the second input voltage is at a low level when the first input voltage is at a high level, and the second input voltage is at the high level when the first input voltage is at the low level; and
wherein the fourth input voltage is at the low level when the third input voltage is at the high level, and the fourth input voltage is at the high level when the third input voltage is at the low level.

13. The motor system as claimed in claim 11, wherein safety unit operates when the second input voltage at a high level.

14. The motor system as claimed in claim 9,
wherein the first voltage level shift unit comprises a first P-type metal oxide semiconductor (PMOS), a first N-type metal oxide semiconductor (NMOS), a second PMOS, and a second NMOS; and
wherein the second voltage level shift unit comprises a third PMOS, a third NMOS, a fourth PMOS, and a fourth NMOS.

15. The motor system as claimed in claim 9, wherein the logic unit comprises a NOR gate, a NAND gate, and a plurality of inverters.
